(19) United States
(12) Patent Application Publication
(10) Pub. No.: US 2026/0271606 A1
(43) Pub. Date: Sep. 10, 2026

(54) DISPLAY DEVICE AND ELECTRONIC DEVICE

(71) Applicant: Samsung Display Co., Ltd., Yongin-si (KR)

(72) Inventors: Kyung Bae KIM, Yongin-si (KR); Kyeong Min PARK, Yongin-si (KR); Gyung Soon PARK, Yongin-si (KR); Keon Min OH, Yongin-si (KR)

(21) Appl. No.: 19/331,877

(22) Filed: Sep. 17, 2025

(30) Foreign Application Priority Data
Mar. 6, 2025 (KR) 10-2025-0028848

(51) Int. Cl. H10K 59/95; H10K 59/131; H10K 59/35

(52) U.S. Cl. CPC H10K 59/95; H10K 59/131; H10K 59/352; H10K 59/353

(57) ABSTRACT

A display device includes: a main display panel including a first side extending along a first direction and a second side adjacent to the first side and extending along a second direction intersecting an extension direction of the first side; a first sub-display panel on the first side of the main display panel and extending along the first direction; a second sub-display panel on the second side of the main display panel and extending along the second direction; a first sub-circuit board connected to the first sub-display panel and overlapping a first side of the first sub-display panel; and a second sub-circuit board connected to the second sub-display panel so as to overlap a first side of the second sub-display panel, wherein the first side of the first sub-display panel extends in the first direction, and the first side of the second sub-display panel extends in the second direction.

### CROSS-REFERENCE TO RELATED APPLICATION

The present application claims priority to and the benefit of Korean Patent Application No. 10-2025-0028848, filed on Mar. 6, 2025, in the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of the Related Art

An organic light emitting display device includes a display element whose luminance is changed by current, for example, an organic light emitting diode.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic device including the same, and for example, to a display device and electronic device capable of preventing or reducing interference and collision between sub-circuit boards.

Aspects of some embodiments of the present disclosure include a display device and electronic device capable of preventing or reducing interference and collision between sub-circuit boards.

According to some embodiments of the present disclosure, a display device includes: a main display panel including a first side extending along a first direction and a second side adjacent to the first side and extending along a second direction intersecting an extension direction of the first side; a first sub-display panel on the first side of the main display panel and extending along the first direction; a second sub-display panel on the second side of the main display panel and extending along the second direction; a first sub-circuit board connected to the first sub-display panel so as to overlap a first side of the first sub-display panel; and a second sub-circuit board connected to the second sub-display panel so as to overlap a first side of the second sub-display panel, wherein the first side of the first sub-display panel extends in the first direction, and the first side of the second sub-display panel extends in the second direction.

According to some embodiments of the present disclosure, an electronic device includes a display device providing a display screen, wherein the display device includes: a main display panel including a first side extending along a first direction and a second side adjacent to the first side and extending along a second direction intersecting an extension direction of the first side; a first sub-display panel on the first side of the main display panel and extending along the first direction; a second sub-display panel on the second side of the main display panel and extending along the second direction; a first sub-circuit board connected to the first sub-display panel so as to overlap a first side of the first sub-display panel; and a second sub-circuit board connected to the second sub-display panel so as to overlap a first side of the second sub-display panel, the first side of the first sub-display panel extends in the first direction, and the first side of the second sub-display panel extends in the second direction.

According to some embodiments, the interference and collision between the sub-circuit boards may be prevented or reduced.

For example, the sub-circuit boards connected to the sub-display panels adjacent to each other may extend in different directions. For example, the first sub-circuit board extends along the second direction, while the fourth sub-circuit board adjacent to the first sub-circuit board extends along the first direction, so that the interference and collision between the first sub-circuit board and the fourth sub-circuit board may be prevented or reduced.

In addition, because the signal lines that extend in the same direction and are included in the sub-display panels that extend in different directions have different widths, a deviation in voltage drops of the signal lines of different sub-display panels may be minimized. Accordingly, an image quality of the display device may be relatively improved.

The characteristics of embodiments according to the present disclosure are not limited to the above-described characteristics and other characteristics which are not described herein will become apparent to those skilled in the art from the following description.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a plan view of a display device according to some embodiments;

FIG. 2 is a view illustrating a back surface of the display device of FIG. 1;

FIG. 3 is an exploded plan view illustrating a state in which a plurality of display panels of FIG. 1 are separated and disassembled;

FIG. 4 is a plan view of a first sub-display panel of FIG. 1;

FIG. 5 is a plan view of a third sub-display panel of FIG. 1;

FIG. 6 is an enlarged view of area A1 of FIG. 4 and area A2 of FIG. 5;

FIG. 7 is a plan view of another example of the first sub-display panel of FIG. 1;

FIG. 8 is a cross-sectional view of a main display panel of FIG. 1;

FIG. 9 is a cross-sectional view of the first sub-display panel of FIG. 1;

FIG. 10 is a block diagram of an electronic display device according to some embodiments; and

FIGS. 11, 12, and 13 are schematic diagrams of electronic devices according to various embodiments.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments will be described in more detail with reference to the accompanying drawings.

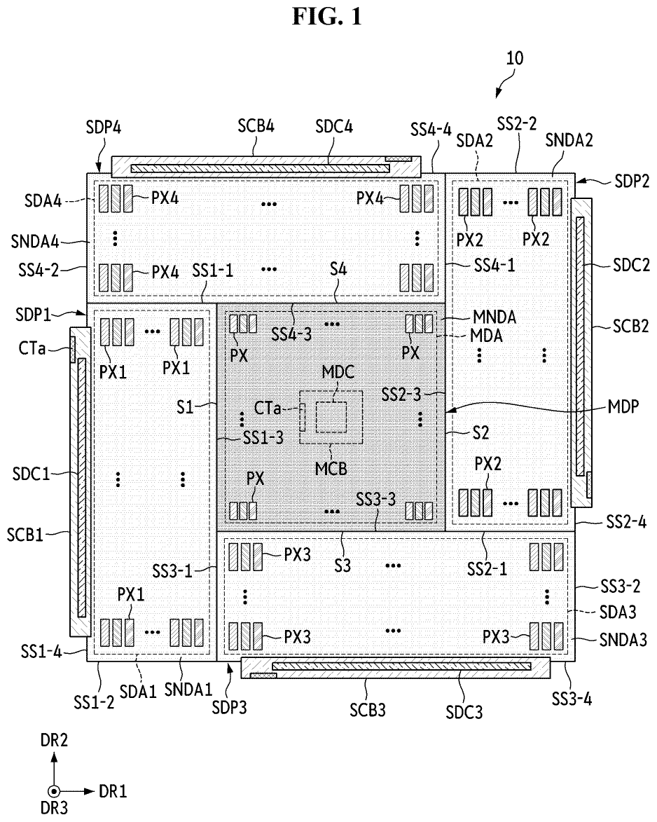

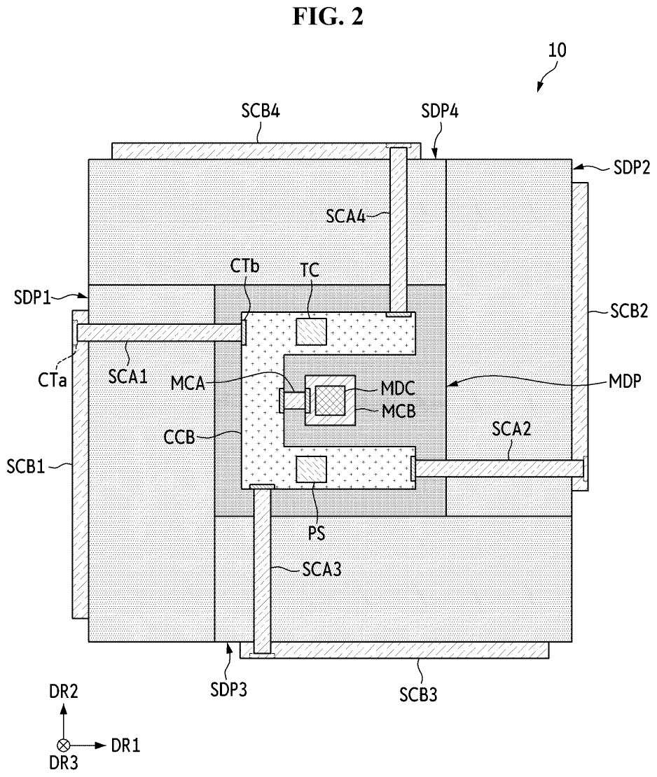

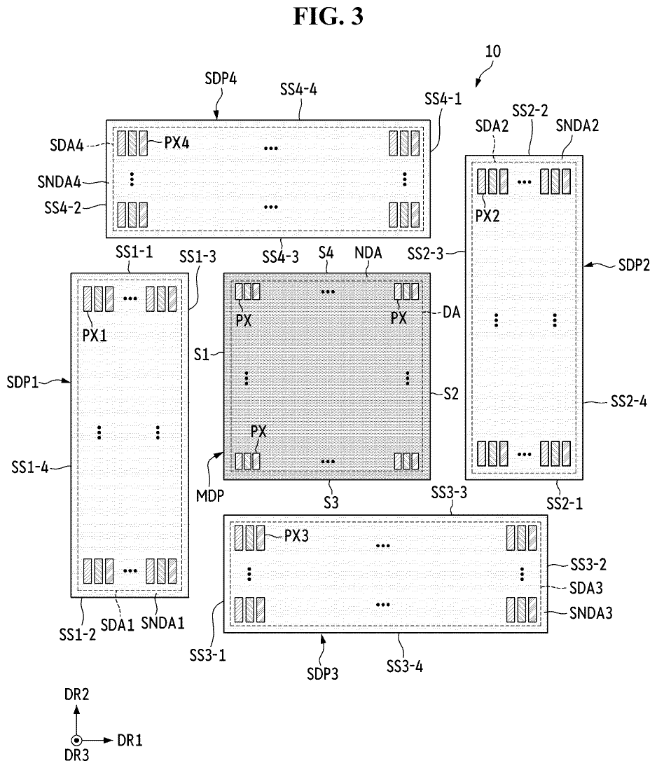

FIG. 1 is a plan view of a display device 10 according to some embodiments, FIG. 2 is a view illustrating a back surface of the display device 10 of FIG. 1, and FIG. 3 is an exploded plan view illustrating a state in which a plurality of display panels of FIG. 1 are separated and disassembled. For convenience of explanation, sub-circuit boards of FIG. 1 are omitted in FIG. 3.

As illustrated in FIGS. 1 to 3, the display device 10 according to some embodiments may include a plurality of display panels (e.g., a main display panel MDP, a first sub-display panel SDP1, a second sub-display panel SDP2, a third sub-display panel SDP3, and a fourth sub-display panel SDP4), a main circuit board MCB, a first sub-circuit board SCB1, a second sub-circuit board SCB2, a third sub-circuit board SCB3, a fourth sub-circuit board SCB4, a common circuit board CCB, a main driving circuit MDC, a first sub-driving circuit SDC1, a second sub-driving circuit SDC2, a third sub-driving circuit SDC3, a fourth sub-driving circuit SDC4, a main cable MCA, a first sub-cable SCA1, a second sub-cable SCA2, a third sub-cable SCA3, a fourth sub-cable SCA4, and a plurality of connectors CTa and CTb.

The plurality of display panels (e.g., the main display panel MDP, the first sub-display panel SDP1, the second sub-display panel SDP2, the third sub-display panel SDP3, and the fourth sub-display panel SDP4) may be connected to each other to form a single unit display panel. The main display panel MDP, the first sub-display panel SDP1, the second sub-display panel SDP2, the third sub-display panel SDP3, and the fourth sub-display panel SDP4 may be connected to each other by an adhesive member, for example.

The main display panel MDP may include a display area DA and a non-display area NDA. A plurality of pixels PX may be located in the display area DA of the main display panel MDP. For example, because the main display panel MDP may include an upper surface and a lower surface facing in a third direction DR3, the plurality of pixels PX of the main display panel MDP may be located in the display area DA of the upper surface of the main display panel MDP. The plurality of pixels PX may include pixels PX that provide light of different colors. For example, when three pixels PX located adjacent to each other along one direction (e.g., a first direction DR1) in the display area DA of the main display panel MDP are defined as a first pixel, a second pixel, and a third pixel, respectively, the first pixel among the three pixels PX may be a red pixel that provides red light, the second pixel among the three pixels PX may be a green pixel that provides green light, and the third pixel among the three pixels PX may be a blue pixel that provides blue light. Here, the first pixel, the second pixel, and the third pixel located adjacent to each other among the plurality of pixels PX of the main display panel MDP may form a unit pixel that displays one unit image.

The main circuit board MCB may be located on the lower surface of the main display panel MDP. The main circuit board MCB may be electrically connected to the lower surface of the main display panel MDP. For example, the main circuit board MCB may be connected to the pixels PX of the main display panel MDP through via electrodes that penetrate through a substrate of the main display panel MDP.

The main driving circuit MDC may be located on the main circuit board MCB. The main driving circuit MDC may provide driving signals (e.g., scan signals and data voltages) and power signals necessary for driving the pixels PX of the main display panel MDP. The driving signals and the power signals from the main driving circuit MDC may be supplied to the pixels PX of the main display panel MDP through transmission lines and via electrodes of the main circuit board MCB.

The main display panel MDP may include a first side S1, a second side S2, a third side S3, and a fourth side S4. The first side S1 and the second side S2 may each extend along the second direction DR2, and the third side S3 and the fourth side S4 may each extend along the first direction DR1. The first side S1 may be adjacent to the third side S3 and the fourth side S4, and the third side S3 may be adjacent to the first side S1 and the second side S2. The first side S1 and the second side S2 may face each other in the first direction DR1, and the third side S3 and the fourth side S4 may face each other in the second direction DR2. Here, the third side S3 may be located between one edge of the first side S1 and one edge of the second side S2, and the fourth side S4 may be located between the other edge of the first side S1 and the other edge of the second side S2.

The first sub-display panel SDP1, the second sub-display panel SDP2, the third sub-display panel SDP3, and the fourth sub-display panel SDP4 may be located on the first to fourth sides S1 to S4 of the main display panel MDP so as to surround the main display panel MDP. For example, the first sub-display panel SDP1 may be located on the first side S1 of the main display panel MDP, the second sub-display panel SDP2 may be located on the second side S2 of the main display panel MDP, the third sub-display panel SDP3 may be located on the third side S3 of the main display panel MDP, and the fourth sub-display panel SDP4 may be located on the fourth side S4 of the main display panel MDP.

The first sub-display panel SDP1 may be in contact with the first side S1 of the main display panel MDP, the second sub-display panel SDP2 may be in contact with the second side S2 of the main display panel MDP, the third sub-display panel SDP3 may be in contact with the third side S3 of the main display panel MDP, and the fourth sub-display panel SDP4 may be in contact with the fourth side S4 of the main display panel MDP.

The first sub-display panel SDP1 may include a first side SS1-1, a second side SS1-2, a third side SS1-3, and a fourth side SS1-4. The first side SS1-1 and the second side SS1-2 may each extend along the first direction DR1, and the third side SS1-3 and the fourth side SS1-4 may each extend along the second direction DR2. The first side SS1-1 may be adjacent to the third side SS1-3 and the fourth side SS1-4, and the third side SS1-3 may be adjacent to the first side SS1-1 and the second side SS1-2. The first side SS1-1 and the second side SS1-2 may face each other in the second direction DR2, and the third side SS1-3 and the fourth side SS1-4 may face each other in the first direction DR1. Here, the third side SS1-3 may be located between one edge of the first side SS1-1 and one edge of the second side SS1-2, and the fourth side SS1-4 may be located between the other edge of the first side SS1-1 and the other edge of the second side SS1-2. A length of the first side SS1-1 and a length of the second side SS1-2 may be equal to each other, and a length of the third side SS1-3 and a length of the fourth side SS1-4 may be equal to each other. The length of the third side SS1-3 may be longer than the length of the first side SS1-1. The third side SS1-3 of the first sub-display panel SDP1 may be in contact with the first side S1 of the main display panel MDP. The length of the third side SS1-3 of the first sub-display panel SDP1 may be longer than a length of the first side S1 of the main display panel MDP.

The first sub-display panel SDP1 may extend in a reverse direction of the second direction DR2 (hereinafter, referred to as a second reverse direction) along the first side S1 on the first side S1 of the main display panel MDP. An extension line of the fourth side S4 of the main display panel MDP may be located on the same line as the first side SS1-1 of the first sub-display panel SDP1, and an extension line of the third side S3 of the main display panel MDP may overlap the first sub-display panel SDP1 so as to intersect an extension direction of the first sub-display panel SDP1. For example, the extension line of the third side S3 of the main display panel MDP may be located between the first side SS1-1 and the second side SS1-2 of the first sub-display panel SDP1.

The second sub-display panel SDP2 may include a first side SS2-1, a second side SS2-2, a third side SS2-3, and a fourth side SS2-4. The first side SS2-1 and the second side SS2-2 may each extend along the first direction DR1, and the third side SS2-3 and the fourth side SS2-4 may each extend along the second direction DR2. The first side SS2-1 may be adjacent to the third side SS2-3 and the fourth side SS2-4, and the third side SS2-3 may be adjacent to the first side SS2-1 and the second side SS2-2. The first side SS2-1 and the second side SS2-2 may face each other in the second direction DR2, and the third side SS2-3 and the fourth side SS2-4 may face each other in the first direction DR1. Here, the third side SS2-3 may be located between one edge of the first side SS2-1 and one edge of the second side SS2-2, and the fourth side SS2-4 may be located between the other edge of the first side SS2-1 and the other edge of the second side SS2-2. A length of the first side SS2-1 and a length of the second side SS2-2 may be equal to each other, and a length of the third side SS2-3 and a length of the fourth side SS2-4 may be equal to each other. The length of the third side SS2-3 may be longer than the length of the first side SS2-1. The third side SS2-3 of the second sub-display panel SDP2 may be in contact with the second side S2 of the main display panel MDP. The length of the third side SS2-3 of the second sub-display panel SDP2 may be longer than a length of the second side S2 of the main display panel MDP.

The second sub-display panel SDP2 may extend in the second direction DR2 along the second side S2 on the second side S2 of the main display panel MDP. An extension line of the third side S3 of the main display panel MDP may be located on the same line as the first side SS2-1 of the second sub-display panel SDP2, and an extension line of the fourth side S4 of the main display panel MDP may overlap the second sub-display panel SDP2 so as to intersect an extension direction of the second sub-display panel SDP2. For example, the extension line of the fourth side S4 of the main display panel MDP may be located between the first side SS2-1 and the second side SS2-2 of the second sub-display panel SDP2.

The third sub-display panel SDP3 may include a first side SS3-1, a second side SS3-2, a third side SS3-3, and a fourth side SS3-4. The first side SS3-1 and the second side SS3-2 may each extend along the second direction DR2, and the third side SS3-3 and the fourth side SS3-4 may each extend along the first direction DR1. The first side SS3-1 may be adjacent to the third side SS3-3 and the fourth side SS3-4, and the third side SS3-3 may be adjacent to the first side SS3-1 and the second side SS3-2. The first side SS3-1 and the second side SS3-2 may face each other in the first direction DR1, and the third side SS3-3 and the fourth side SS3-4 may face each other in the second direction DR2. Here, the third side SS3-3 may be located between one edge of the first side SS3-1 and one edge of the second side SS3-2, and the fourth side SS3-4 may be located between the other edge of the first side SS3-1 and the other edge of the second side SS3-2. A length of the first side SS3-1 and a length of the second side SS3-2 may be equal to each other, and a length of the third side SS3-3 and a length of the fourth side SS3-4 may be equal to each other. The length of the third side SS3-3 may be longer than the length of the first side SS3-1. The third side SS3-3 of the third sub-display panel SDP3 may be in contact with the third side S3 of the main display panel MDP. The length of the third side SS3-3 of the third sub-display panel SDP3 may be longer than a length of the third side S3 of the main display panel MDP.

The third sub-display panel SDP3 may extend in the first direction DR1 along the third side S3 on the third side S3 of the main display panel MDP. An extension line of the first side S1 of the main display panel MDP may be located on the same line as the first side SS3-1 of the third sub-display panel SDP3, and an extension line of the second side S2 of the main display panel MDP may overlap the third sub-display panel SDP3 so as to intersect an extension direction of the third sub-display panel SDP3. For example, the extension line of the second side S2 of the main display panel MDP may be located between the first side SS3-1 and the second side SS3-2 of the third sub-display panel SDP3.

The fourth sub-display panel SDP4 may include a first side SS4-1, a second side SS4-2, a third side SS4-3, and a fourth side SS4-4. The first side SS4-1 and the second side SS4-2 may each extend along the second direction DR2, and the third side SS4-3 and the fourth side SS4-4 may each extend along the first direction DR1. The first side SS4-1 may be adjacent to the third side SS4-3 and the fourth side SS4-4, and the third side SS4-3 may be adjacent to the first side SS4-1 and the second side SS4-2. The first side SS4-1 and the second side SS4-2 may face each other in the first direction DR1, and the third side SS4-3 and the fourth side SS4-4 may face each other in the second direction DR2. Here, the third side SS4-3 may be located between one edge of the first side SS4-1 and one edge of the second side SS4-2, and the fourth side SS4-4 may be located between the other edge of the first side SS4-1 and the other edge of the second side SS4-2. A length of the first side SS4-1 and a length of the second side SS4-2 may be equal to each other, and a length of the third side SS4-3 and a length of the fourth side SS4-4 may be equal to each other. The length of the third side SS4-3 may be longer than the length of the first side SS4-1. The third side SS4-3 of the fourth sub-display panel SDP4 may be in contact with the fourth side S4 of the main display panel MDP. The length of the third side SS4-3 of the fourth sub-display panel SDP4 may be longer than a length of the fourth side S4 of the main display panel MDP.

The fourth sub-display panel SDP4 may extend in a reverse direction of the first direction DR1 (hereinafter, referred to as a first reverse direction) along the fourth side S4 on the fourth side S4 of the main display panel MDP. An extension line of the second side S2 of the main display panel MDP may be located on the same line as the first side SS4-1 of the fourth sub-display panel SDP4, and an extension line of the first side S1 of the main display panel MDP may overlap the fourth sub-display panel SDP4 so as to intersect an extension direction of the fourth sub-display panel SDP4. For example, the extension line of the first side S1 of the main display panel MDP may be located between the first side SS4-1 and the second side SS4-2 of the fourth sub-display panel SDP4.

The first side SS1-1 of the first sub-display panel SDP1 may be in contact with the third side SS4-3 of the fourth sub-display panel SDP4, and the third side SS1-3 of the first sub-display panel SDP1 may be in contact with the first side S1 of the main display panel MDP and the first side SS3-1 of the third sub-display panel SDP3. Here, the length of the third side SS1-3 of the first sub-display panel SDP1 may be equal to the sum of the length of the first side S1 of the main display panel MDP and the length of the first side SS3-1 of the third sub-display panel SDP3. The length of the fourth side SS1-4 of the first sub-display panel SDP1 may be equal to the length of the third side SS1-3 of the first sub-display panel SDP1.

The first side SS2-1 of the second sub-display panel SDP2 may be in contact with the third side SS3-3 of the third sub-display panel SDP3, and the third side SS2-3 of the second sub-display panel SDP2 may be in contact with the second side S2 of the main display panel MDP and the first side SS4-1 of the fourth sub-display panel SDP4. Here, the length of the third side SS2-3 of the second sub-display panel SDP2 may be equal to the sum of the length of the second side S2 of the main display panel MDP and the length of the first side SS4-1 of the fourth sub-display panel SDP4. The length of the fourth side SS2-4 of the second sub-display panel SDP2 may be equal to the length of the third side SS2-3 of the second sub-display panel SDP2.

The first side SS3-1 of the third sub-display panel SDP3 may be in contact with the third side SS1-3 of the first sub-display panel SDP1, and the third side SS3-3 of the third sub-display panel SDP3 may be in contact with the third side S3 of the main display panel MDP and the first side SS2-1 of the second sub-display panel SDP2. Here, the length of the third side SS3-3 of the third sub-display panel SDP3 may be equal to the sum of the length of the third side S3 of the main display panel MDP and the length of the first side SS2-1 of the second sub-display panel SDP2. The length of the fourth side SS3-4 of the third sub-display panel SDP3 may be equal to the length of the third side SS3-3 of the third sub-display panel SDP3.

The first side SS4-1 of the fourth sub-display panel SDP4 may be in contact with the third side SS2-3 of the second sub-display panel SDP2, and the third side SS4-3 of the fourth sub-display panel SDP4 may be in contact with the fourth side S4 of the main display panel MDP and the first side SS1-1 of the first sub-display panel SDP1. Here, the length of the third side SS4-3 of the fourth sub-display panel SDP4 may be equal to the sum of the length of the fourth side S4 of the main display panel MDP and the length of the first side SS1-1 of the first sub-display panel SDP1. The length of the fourth side SS4-4 of the fourth sub-display panel SDP4 may be equal to the length of the third side SS4-3 of the fourth sub-display panel SDP4.

The first sub-display panel SDP1 may include a display area SDA1 and a non-display area SNDA1. A plurality of pixels PX1 may be located in the display area SDA1 of the first sub-display panel SDP1. The plurality of pixels PX1 may include pixels PX1 that provide light of different colors. For example, when three pixels PX1 located adjacent to each other along one direction (e.g., the first direction DR1) in the display area SDA1 of the first sub-display panel SDP1 are defined as a first pixel, a second pixel, and a third pixel, respectively, the first pixel among the three pixels PX1 may be a red pixel that provides red light, the second pixel among the three pixels PX1 may be a green pixel that provides green light, and the third pixel among the three pixels PX1 may be a blue pixel that provides blue light. Here, the first pixel, the second pixel, and the third pixel located adjacent to each other among the plurality of pixels PX1 of the first sub-display panel SDP1 may form a unit pixel that displays one unit image.

The first sub-circuit board SCB1 may be connected to the non-display area SNDA1 of the first sub-display panel SDP1. For example, one side of the first sub-circuit board SCB1 may be electrically connected to pads located in the non-display area SNDA1 of the first sub-display panel SDP1 through a conductive adhesive member. The first sub-circuit board SCB1 may be connected to the first sub-display panel SDP1 so as to overlap the fourth side SS1-4 of the first sub-display panel SDP1. The first sub-circuit board SCB1 may extend along the fourth side SS1-4 of the first sub-display panel SDP1. For example, the first sub-circuit board SCB1 may overlap the fourth side SS1-4 among two long sides of the first sub-display panel SDP1 that is located further from the first side S1 of the main display panel MDP, and may extend along the fourth side SS1-4.

The first sub-driving circuit SDC1 may be located on the first sub-circuit board SCB1. The first sub-driving circuit SDC1 may provide driving signals (e.g., scan signals and data voltages) and power signals necessary for driving the pixels PX1 of the first sub-display panel SDP1. The driving signals and the power signals from the first sub-driving circuit SDC1 may be supplied to the pixels PX1 of the first sub-display panel SDP1 through transmission lines of the first sub-circuit board SCB1 and pads of the first sub-display panel SDP1.

The second sub-display panel SDP2 may include a display area SDA2 and a non-display area SNDA2. A plurality of pixels PX2 may be located in the display area SDA2 of the second sub-display panel SDP2. The plurality of pixels PX2 may include pixels PX2 that provide light of different colors. For example, when three pixels PX2 located adjacent to each other along one direction (e.g., the first direction DR1) in the display area SDA2 of the second sub-display panel SDP2 are defined as a first pixel, a second pixel, and a third pixel, respectively, the first pixel among the three pixels PX2 may be a red pixel that provides red light, the second pixel among the three pixels PX2 may be a green pixel that provides green light, and the third pixel among the three pixels PX2 may be a blue pixel that provides blue light. Here, the first pixel, the second pixel, and the third pixel located adjacent to each other among the plurality of pixels PX2 of the second sub-display panel SDP2 may form a unit pixel that displays one unit image.

The second sub-circuit board SCB2 may be connected to the non-display area SNDA2 of the second sub-display panel SDP2. For example, one side of the second sub-circuit board SCB2 may be electrically connected to pads located in the non-display area SNDA2 of the second sub-display panel SDP2 through a conductive adhesive member. The second sub-circuit board SCB2 may be connected to the second sub-display panel SDP2 so as to overlap the fourth side SS2-4 of the second sub-display panel SDP2. The second sub-circuit board SCB2 may extend along the fourth side SS2-4 of the second sub-display panel SDP2. For example, the second sub-circuit board SCB2 may overlap the fourth side SS2-4 among two long sides of the second sub-display panel SDP2 that is located further from the second side S2 of the main display panel MDP, and may extend along the fourth side SS2-4.

The second sub-driving circuit SDC2 may be located on the second sub-circuit board SCB2. The second sub-driving circuit SDC2 may provide driving signals (e.g., scan signals and data voltages) and power signals necessary for driving the pixels PX2 of the second sub-display panel SDP2. The driving signals and the power signals from the second sub-driving circuit SDC2 may be supplied to the pixels PX2 of the second sub-display panel SDP2 through transmission lines of the second sub-circuit board SCB2 and pads of the second sub-display panel SDP2.

The third sub-display panel SDP3 may include a display area SDA3 and a non-display area SNDA3. A plurality of pixels PX3 may be located in the display area SDA3 of the third sub-display panel SDP3. The plurality of pixels PX3 may include pixels PX3 that provide light of different colors. For example, when three pixels PX3 located adjacent to each other along one direction (e.g., the first direction DR1) in the display area SDA3 of the third sub-display panel SDP3 are defined as a first pixel, a second pixel, and a third pixel, respectively, the first pixel among the three pixels PX2 may be a red pixel that provides red light, the second pixel among the three pixels PX2 may be a green pixel that provides green light, and the third pixel among the three pixels PX2 may be a blue pixel that provides blue light. Here, the first pixel, the second pixel, and the third pixel located adjacent to each other among the plurality of pixels PX3 of the third sub-display panel SDP3 may form a unit pixel that displays one unit image.

The third sub-circuit board SCB3 may be connected to the non-display area SNDA3 of the third sub-display panel SDP3. For example, one side of the third sub-circuit board SCB3 may be electrically connected to pads located in the non-display area SNDA3 of the third sub-display panel SDP3 through a conductive adhesive member. The third sub-circuit board SCB3 may be connected to the third sub-display panel SDP3 so as to overlap the fourth side SS3-4 of the third sub-display panel SDP3. The third sub-circuit board SCB3 may extend along the fourth side SS3-4 of the third sub-display panel SDP3. For example, the third sub-circuit board SCB3 may overlap the fourth side SS3-4 among two long sides of the third sub-display panel SDP3 that is located further from the third side S3 of the main display panel MDP, and may extend along the fourth side SS3-4.

The third sub-driving circuit SDC3 may be located on the third sub-circuit board SCB3. The third sub-driving circuit SDC3 may provide driving signals (e.g., scan signals and data voltages) and power signals necessary for driving the pixels PX3 of the third sub-display panel SDP3. The driving signals and the power signals from the third sub-driving circuit SDC3 may be supplied to the pixels PX3 of the third sub-display panel SDP3 through transmission lines of the third sub-circuit board SCB3 and pads of the third sub-display panel SDP3.

The fourth sub-display panel SDP4 may include a display area SDA4 and a non-display area SNDA4. A plurality of pixels PX4 may be located in the display area SDA4 of the fourth sub-display panel SDP4. The plurality of pixels PX4 may include pixels PX4 that provide light of different colors. For example, when three pixels PX4 located adjacent to each other along one direction (e.g., the first direction DR1) in the display area SDA4 of the fourth sub-display panel SDP4 are defined as a first pixel, a second pixel, and a third pixel, respectively, the first pixel among the three pixels PX4 may be a red pixel that provides red light, the second pixel among the three pixels PX4 may be a green pixel that provides green light, and the third pixel among the three pixels PX4 may be a blue pixel that provides blue light. Here, the first pixel, the second pixel, and the third pixel located adjacent to each other among the plurality of pixels PX4 of the fourth sub-display panel SDP4 may form a unit pixel that displays one unit image.

The fourth sub-circuit board SCB4 may be connected to the non-display area SNDA4 of the fourth sub-display panel SDP4. For example, one side of the fourth sub-circuit board SCB4 may be electrically connected to pads located in the non-display area SNDA4 of the fourth sub-display panel SDP4 through a conductive adhesive member. The fourth sub-circuit board SCB4 may be connected to the fourth sub-display panel SDP4 so as to overlap the fourth side SS4-4 of the fourth sub-display panel SDP4. The fourth sub-circuit board SCB4 may extend along the fourth side SS4-4 of the fourth sub-display panel SDP4. For example, the fourth sub-circuit board SCB4 may overlap the fourth side SS4-4 among two long sides of the fourth sub-display panel SDP4 that is located further from the fourth side S4 of the main display panel MDP, and may extend along the fourth side SS4-4.

The fourth sub-driving circuit SDC4 may be located on the fourth sub-circuit board SCB4. The fourth sub-driving circuit SDC4 may provide driving signals (e.g., scan signals and data voltages) and power signals necessary for driving the pixels PX4 of the fourth sub-display panel SDP4. The driving signals and the power signals from the fourth sub-driving circuit SDC4 may be supplied to the pixels PX4 of the fourth sub-display panel SDP4 through transmission lines of the fourth sub-circuit board SCB4 and pads of the fourth sub-display panel SDP4.

The common circuit board CCB may be located on the lower surface of the main display panel MDP. The common circuit board CCB may be electrically connected to the main circuit board MCB, the first sub-circuit board SCB1, the second sub-circuit board SCB2, the third sub-circuit board SCB3, and the fourth sub-circuit board SCB4. For example, the common circuit board CCB and the main circuit board MCB may be electrically connected to each other through the main cable MCA, the common circuit board CCB and the first sub-circuit board SCB1 may be electrically connected to each other through the first sub-cable SCA1, the common circuit board CCB and the second sub-circuit board SCB2 may be electrically connected to each other through the second sub-cable SCA2, the common circuit board CCB and the third sub-circuit board SCB3 may be electrically connected to each other through the third sub-cable SCA3, and the common circuit board CCB and the fourth sub-circuit board SCB4 may be electrically connected to each other through the fourth sub-cable SCA4. In this case, each cable MCA, SCA1, SCA2, SCA3, and SCA4 may be connected to the corresponding cable of the common circuit board CCB and the corresponding connector CTa and CTb of each circuit board.

A timing controller TC and a power supply PS may be located on the common circuit board CCB. The timing controller TC may provide scan control signals, timing control signals, data signals, etc., and the power supply PS may provide power signals. The scan control signals, the timing control signals, and the data signals from the timing controller TC and the power signals from the power supply PS may be supplied to the main driving circuit MDC through the common circuit board CCB, the main cable MCA, and the main circuit board MCB. In addition, the scan control signals, the timing control signals, and the data signals from the timing controller TC and the power signals from the power supply PS may be supplied to the first sub-driving circuit SDC1 through the common circuit board CCB, the first sub-cable SCA1, and the first sub-circuit board SCB1. In addition, the scan control signals, the timing control signals, and the data signals from the timing controller TC and the power signals from the power supply PS may be supplied to the second sub-driving circuit SDC2 through the common circuit board CCB, the second sub-cable SCA2, and the second sub-circuit board SCB2. In addition, the scan control signals, the timing control signals, and the data signals from the timing controller TC and the power signals from the power supply PS may be supplied to the third sub-driving circuit SDC3 through the common circuit board CCB, the third sub-cable SCA3, and the third sub-circuit board SCB3. In addition, the scan control signals, the timing control signals, and the data signals from the timing controller TC and the power signals from the power supply PS may be supplied to the fourth sub-driving circuit SDC4 through the common circuit board CCB, the fourth sub-cable SCA4, and the fourth sub-circuit board SCB4.

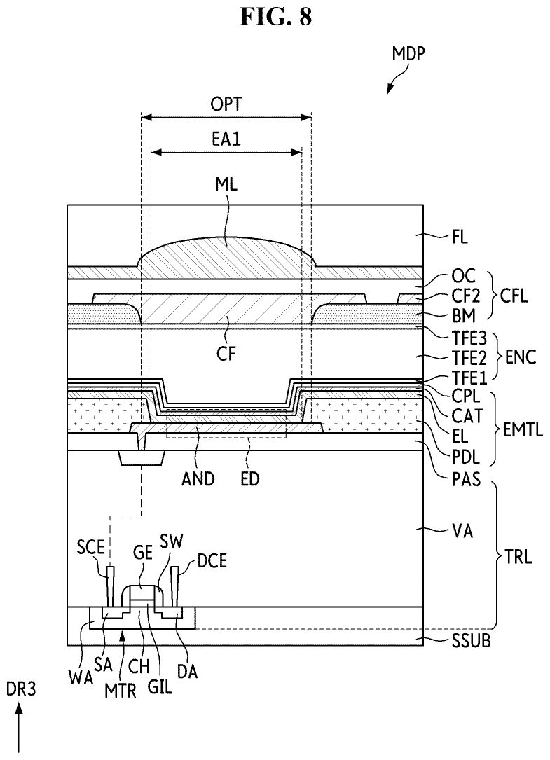

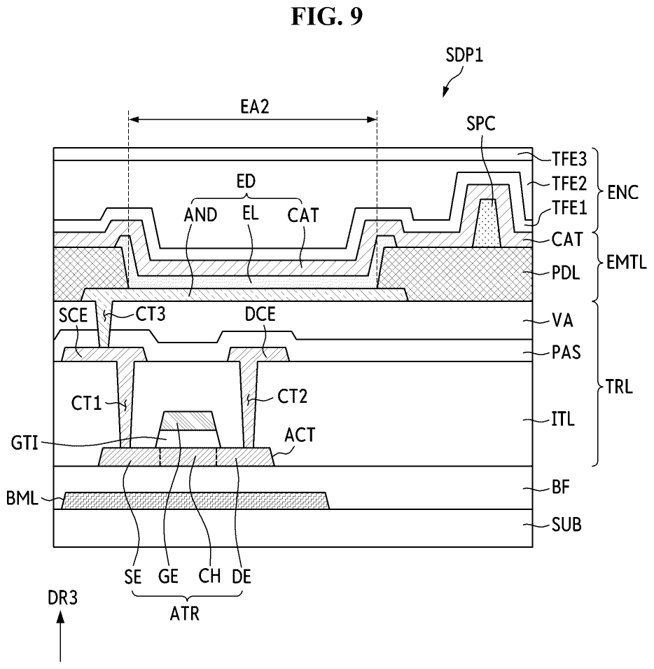

The pixels PX of the main display panel MDP and the pixels of the sub-display panel may have different areas. For example, the area of the pixel PX of the main display panel MDP may be smaller than the area of the pixel PX1 of the first sub-display panel SDP1. In addition, areas of the pixels PX1 to PX4 of the respective sub-display panels SDP1 to SDP4 may be the same. For example, the pixel PX1 of the first sub-display panel SDP1, the pixel PX2 of the second sub-display panel SDP2, the pixel PX3 of the third sub-display panel SDP3, and the pixel PX4 of the fourth sub-display panel SDP4 may have the same area. Here, the area of the pixel described above may mean, for example, a size of a light emitting area of the pixel. As a specific example, an area of a light emitting area (e.g., EA1 in FIG. 8) of the pixel PX included in the main display panel MDP may be smaller than an area of a light emitting area (e.g., EA2 in FIG. 9) of the pixel PX1 included in the first sub-display panel SDP1.

According to some embodiments, the sub-circuit boards connected to the sub-display panels adjacent to each other may extend in different directions. Therefore, the interference and collision between the sub-circuit boards adjacent to each other may be prevented or reduced. For example, the first sub-circuit board SCB1 extends along the second direction DR2, while the fourth sub-circuit board SCB4 located adjacent to the first sub-circuit board SCB1 extends along the first direction DR1. Therefore, the interference and collision between the first sub-circuit board SCB1 and the fourth sub-circuit board SCB4 may be prevented or reduced.

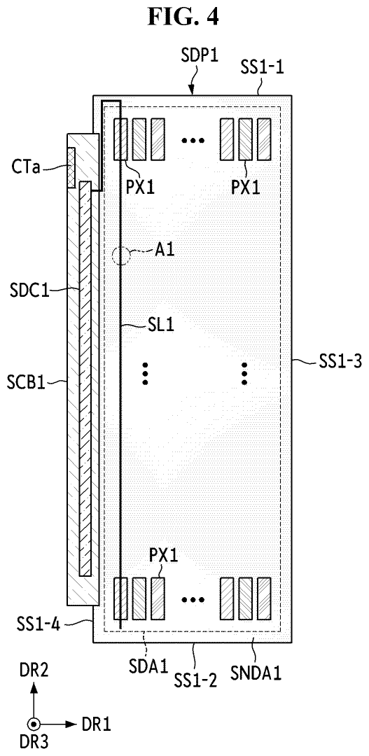

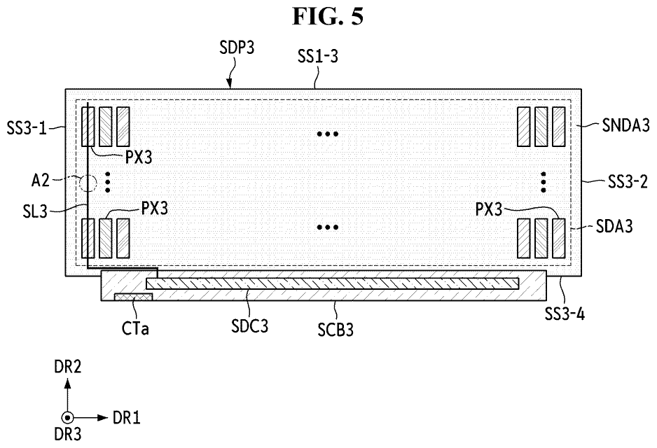

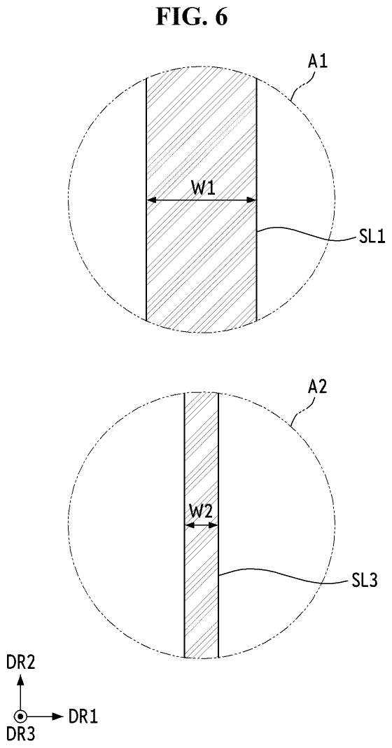

FIG. 4 is a plan view of a first sub-display panel of FIG. 1, FIG. 5 is a plan view of a third sub-display panel of FIG. 1, and FIG. 6 is an enlarged view of area A1 of FIG. 4 and area A2 of FIG. 5.

As illustrated in FIG. 4, the first sub-driving circuit SDC1 may be connected to the first pixel through a first signal line SL1. Here, the first signal line SL1 may include either a scan line transmitting a scan signal or a data line transmitting a data voltage.

The first signal line SL1 may be connected to the first sub-driving circuit SDC1 and the pixel PX1.

The first signal line SL1 may be located in the display area SDA1 of the first sub-display panel SDP1.

The first signal line SL1 may extend along the extension direction of the first sub-display panel SDP1 (e.g., the second direction DR2). In other words, the first signal line SL1 may extend along a longitudinal direction of the third side SS1-3 or the fourth side SS1-4, which is the long side of the first sub-display panel SDP1, in the display area SDA1 of the first sub-display panel SDP1.

As illustrated in FIG. 5, the third sub-driving circuit SDC3 may be connected to the pixel PX3 through a third signal line SL3. Here, the third signal line SL3 may include either a scan line transmitting a scan signal or a data line transmitting a data voltage.

The third signal line SL3 may be connected to the third sub-driving circuit SDC3 and the pixel PX3.

The third signal line SL3 may be located in the display area SDA3 of the third sub-display panel SDP3.

The third signal line SL3 may extend along a direction (e.g., the second direction DR2) interesting the extension direction of the third sub-display panel SDP3 (e.g., the first direction DR1). In other words, the third signal line SL3 may extend along a longitudinal direction of the first side SS3-1 or the fourth side SS3-4, which is the short side of the third sub-display panel SDP3, in the display area SDA3 of the third sub-display panel SDP3.

In this way, the signal lines of the sub-display panels extending in different directions may have different lengths. For example, a length of the first signal line SL1 of the first sub-display panel SDP1 may be longer than a length of the third signal line SL3 of the third sub-display panel SDP3. In this case, as illustrated in FIG. 6, a width W1 (e.g., line width) of the first signal line SL1 having a relatively longer length may be greater than a width W2 of the third signal line SL3 having of a relatively shorter length. Accordingly, a voltage drop in the first signal line SL1 and a voltage drop in the third signal line SL3 may have almost the same size. In other words, a deviation between the voltage drop in the first signal line SL1 and the voltage drop in the third signal line SL3 may be minimized. Accordingly, a deviation in image quality between the first sub-display panel SDP1 and the second sub-display panel SDP2 extending in different directions may be minimized, thereby relatively improving an image quality of the display device 10.

The second signal line of the second sub-display panel SDP2 extending in the same direction (e.g., the second direction DR2) as the first sub-display panel SDP1 may have the same width W1 as the first signal line SL1 of the first sub-display panel SDP1 described above. For example, the width of the second signal line and the width W1 of the first signal line SL1 may be the same. Similarly, the fourth signal line of the fourth sub-display panel SDP4 extending in the same direction (e.g., the first direction DR1) as the third sub-display panel SDP3 may have the same width W2 as the second signal line SL2 of the second sub-display panel SDP2 described above. For example, the width of the fourth signal line and the width W2 of the second signal line may be the same.

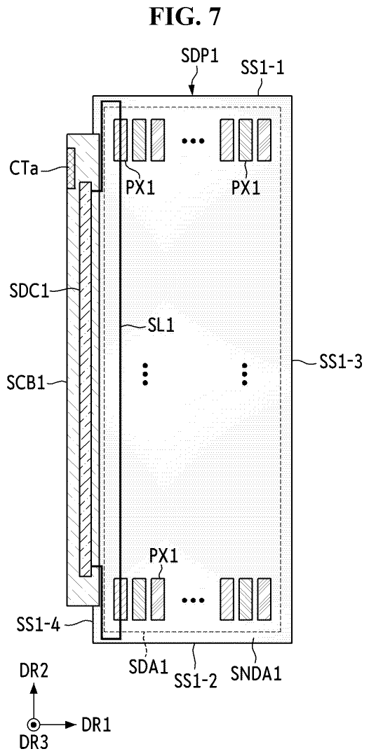

FIG. 7 is a plan view of another example of the first sub-display panel SDP1 of FIG. 1.

The first sub-display panel SDP1 of FIG. 7 has a difference from the first sub-display panel SDP1 of FIG. 4 described above in the first signal line SL1, and the difference will be mainly described as follows.

As illustrated in FIG. 7, the first signal line SL1 may have one end and the other end each connected to the first sub-driving circuit SDC1. Accordingly, the first sub-driving circuit SDC1 may supply a signal (e.g., a scan signal or a data voltage) to one end and the other end of the first signal line SL1, respectively. Therefore, distortion of the signal transmitted through the first signal line SL1 may be minimized.

FIG. 8 is a cross-sectional view of a main display panel MDP of FIG. 1.

As illustrated in FIG. 8, the main display panel MDP may include a substrate SSUB (e.g., a semiconductor substrate or wafer), a transistor layer TRL, a light emitting element layer EMTL, an encapsulation layer ENC, a color filter layer CFL, a lens (e.g., a micro lens), and a filling layer FL.

The substrate SSUB may be a silicon substrate, a germanium substrate, or a silicon-germanium substrate. The substrate SSUB may be a substrate doped with first-type impurities.

A well area WA may be located in the substrate SSUB. The well area WA may be an area doped with second-type impurities. The second-type impurity may be different from the first-type impurity described above. For example, when the first type impurity is a p-type impurity, the second type impurity may be an n-type impurity. When the first type impurity is an n-type impurity, the second type impurity may be a p-type impurity.

A source area SA, a drain area D, and a channel area CH of a transistor MTR may be located in the well area W. For example, a source area SA (or a source electrode) and a drain area DA (or a drain electrode) of the transistor TR may be located in the well area WA. Each of the source area SA and the drain area DA may be an area doped with the first-type impurities described above. A gate electrode GE of the transistor TR may intersect and overlap the well area WA. In plan view, the well area WA intersecting the gate electrode GE may be defined as two areas, and the source area SA may be located in one of the two areas, and the drain area DA may be located in the other area. In other words, in the well area W, the source area SA and the drain area DA may be located on respective sides of the gate electrode GE with the gate electrode GE interposed therebetween. The channel area CH of the transistor MTR may be located in an area of the well area WA overlapping the gate electrode GE. The transistor MTR may be, for example, a Metal-Oxide-Semiconductor (MOS) transistor.

The drain area DA of the transistor MTR may be connected to a drain connection electrode DCE.

A gate insulating layer GIL may be located between the channel area CH and the gate electrode GE.

An interlayer insulating layer VA may be located on the substrate SSUB.

A passivation layer PAS may be located on the interlayer insulating layer VA.

A light emitting element layer EMTL may be located on the passivation layer PAS. The light emitting element layer EMTL may include a light emitting element ED. For example, the light emitting element ED of the light emitting element layer EMTL may be located in the light emitting area EA1.

The light emitting element ED may include a first electrode AND (e.g., an anode electrode), a light emitting layer EL, and a second electrode CAT that are stacked in a third direction DR3.

The first electrode AND may be connected to the source area SA of the transistor MTR through a source connection electrode SCE.

The first electrode AND may be arranged to correspond to the light emitting area EA1.

A pixel defining layer PDL may be located on the first electrode AND.

The pixel defining layer PDL may define the light emitting area EA1 of the pixel. To this end, the pixel defining layer PDL may be arranged, for example, to expose a portion of the first electrode AND on the passivation layer PAS. The pixel defining layer PDL may cover an edge of the first electrode AND.

The light emitting layer EL may be located on the first electrode AND and pixel defining layer PDL. The light emitting layer EL may emit light.

The second electrode CAT may be located on the light emitting layer EL. For example, the second electrode CAT may be located on the light emitting layer EL so as to overlap the first electrode AND, the light emitting area EA1, and the pixel defining layer PDL.

A capping layer CPL may be located on the second electrode CAT. The capping layer CPL may include an inorganic insulating material.

An encapsulation layer ENC may be located on the capping layer CPL. The encapsulation layer ENC may cover an upper surface and side surfaces of the light emitting element layer EMTL, and may protect the light emitting element layer EMTL. The encapsulation layer ENC may include a first encapsulation inorganic layer TFE1, an encapsulation organic layer TFE2, and a second encapsulation inorganic layer TFE3.

The first encapsulation inorganic layer TFE1 may be located on the capping layer CPL, the encapsulation organic layer TFE2 may be located on the first encapsulation inorganic layer TFE1, and the second encapsulation inorganic layer TFE3 may be located on the encapsulation organic layer TFE2. The first encapsulation inorganic layer TFE1 and the second encapsulation inorganic layer TFE3 may be formed as a multi-layer in which one or more inorganic layer of a silicon nitride layer, a silicon oxynitride layer, a silicon oxide layer, a titanium oxide layer, and an aluminum oxide layer are alternately stacked. The encapsulation organic layer TFE2 may be an organic layer including an acryl resin, an epoxy resin, a phenolic resin, a polyamide resin, or a polyimide resin.

The light blocking layer BM may be located on the encapsulation layer ENC. The light blocking layer BM may include a hole OPT arranged to overlap the light emitting area EA1. The area or size of the hole OPT may be greater than the area or size of the light emitting area EA1 defined by the pixel defining layer PDL. As the holes OPT of the light blocking layer BM is formed to be greater than the light emitting area EA1, light emitted from the light emitting area EA1 may be visually recognized by a user not only from a front side of the display device 10 but also from a side surface thereof.

In addition, the display device 10 may include a color filter CF located on the light emitting area EA1. The color filter CF may be arranged to correspond to the light emitting area EA1. For example, the color filter CF may be located on the light blocking layer BM including the hole OPT arranged to correspond to the light emitting area EA1.

An overcoat layer OC may be located on the color filters CF adjacent to each other to planarize upper ends of the color filters CF. The overcoat layer OC may be a colorless light-transmitting layer having no color in a visible light band. For example, the overcoat layer OC may include a colorless light-transmitting organic material such as an acryl-based resin.

A lens ML may be located on the overcoat layer OC. The lens ML may be arranged to correspond to the light emitting area EA1 or the hole OPT.

The lens ML may have a larger size than the hole OPT. For example, the lens ML may completely cover the holes OPT and overlap a portion of the light blocking layer BM.

The filling layer FL may be located on the lens ML. The filling layer FL may be located between the lenses ML adjacent to each other.

FIG. 9 is a cross-sectional view of the first sub-display panel SDP1 of FIG. 1.

As illustrated in FIG. 9, the first sub-display panel SDP1 may include a substrate SUB, a light blocking layer BML, a buffer layer BF, a transistor layer TRL, a light emitting element layer EMTL, and an encapsulation layer ENC. The light blocking layer BML, the buffer layer BF, the transistor layer TRL, the light emitting element layer EMTL, and the encapsulation layer ENC may be sequentially located on the substrate SUB along the third direction DR3.

The substrate SUB may be a rigid substrate SUB or be a flexible substrate SUB that may be bent, folded, rolled, or the like. The substrate SUB may include an insulating material such as glass, quartz, or a polymer resin. Alternatively, the substrate SUB may also include a metal material.

The light blocking layer BML may be located on the substrate SUB. The light blocking layer BML may be located on the substrate SUB to overlap an active layer ACT, which will be described later. The light blocking layer BML may include, for example, a metal material such as chromium (Cr) or molybdenum (Mo), or black ink or black dye.

The buffer layer BF may be located on the light blocking layer BML. The buffer layer BF may be located on an entire surface of the substrate SUB including the light blocking layer BML. The buffer layer BF may be a layer for protecting the transistor ATR of the transistor layer TRL and the light emitting layer EL of the light emitting element layer EMTL from moisture permeating through the substrate SUB vulnerable to moisture permeation.

An active layer ACT may be located on the buffer layer BF. A first active layer ACT1 may be, for example, an oxide semiconductor. For example, the first active layer ACT1 may be a semiconductor including indium-gallium-zinc-oxide (IGZO) or indium-gallium-zinc-tin oxide (IGZTO).

A gate insulating layer GTI may be located on the active layer ACT. For example, the gate insulating layer GTI may be located to overlap a channel area CH of the active layer ACT.

A gate electrode GE may be located on the gate insulating layer GTI. The gate electrode GE may be located on the gate insulating layer GTI to overlap the channel area CH of the active layer ACT.

An interlayer insulating layer ITL may be located on the gate electrode GE. The interlayer insulating layer ITL may be arranged on an entire surface of the substrate SUB including the gate electrode GE.

A source connection electrode SCE and a drain connection electrode DCE may be located on the interlayer insulating layer ITL. The source connection electrode SCE may be connected to a source electrode SE of the active layer ACT through a first contact hole CT1 penetrating through the interlayer insulating layer ITL. The drain connection electrode DCE may be connected to a drain electrode DE of the active layer ACT through a second contact hole CT2 penetrating through the interlayer insulating layer ITL.

A passivation layer PAS may be located on the source connection electrode SCE and the drain connection electrode DCE. The passivation layer PAS may be arranged on an entire surface of the substrate SUB including the interlayer insulating layer ITL.

A planarization layer VA may be located on the passivation layer PAS. The passivation layer PAS may be arranged on an entire surface of the substrate SUB including the planarization layer VA.

A light emitting element layer EMTL including a first electrode AND may be located on the planarization layer VA. The first electrode AND may be connected to the source connection electrode SCE through a third contact hole CT3 penetrating through the planarization layer VA. The first electrode AND may be connected to the source electrode SE of the active layer ACT through the source connection electrode SCE.

The above-described light emitting element layer EMTL may further include a light emitting element ED and a pixel defining layer PDL, in addition to the above-described first electrode AND.

The light emitting element ED may include a first electrode AND, a light emitting layer EL, and a second electrode CAT. The light emitting area EA2 is an area in which the first electrode AND, the light emitting layer EL, and the second electrode CAT are sequentially stacked, and holes from the first electrode AND and electrons from the second electrode CAT are bonded to each other in the light emitting layer to emit light. In this case, the first electrode AND may be an anode electrode of the light emitting element ED, and the second electrode CAT may be a cathode electrode of the light emitting element ED.

The pixel defining layer PDL serves to define the light emitting area EA2 of the first pixel. To this end, the pixel defining layer PDL may be arranged to expose a portion of the first electrode AND on the planarization layer VA. The pixel defining layer PDL may cover an edge of the first electrode AND.

A spacer SPC may be located on the pixel defining layer PDL. The spacer SPC may serve to support a mask during a process of manufacturing the light emitting layer EL.

A light emitting layer EL may be formed on the first electrode AND. The light emitting layer EL may include an organic material to emit light of a color (e.g., a set or predetermined color).

The second electrode CAT may be located on the light emitting layer EL.

The encapsulation layer ENC may be formed on the light emitting element layer EMTL. The encapsulation layer ENC may include one or more inorganic layers TFE1 and TFE3 to prevent or reduce contaminants such as oxygen or moisture permeating into the light emitting element layer EMTL. In addition, the encapsulation layer ENC may include at least one organic layer to protect the light emitting element layer EMTL from foreign substances or contaminants such as dust. For example, the encapsulation layer ENC may include a first encapsulation inorganic layer TFE1, an encapsulation organic layer TFE2, and a second encapsulation inorganic layer TFE3.

The display device 10 according to some embodiments may be applied to various electronic devices. An electronic device according to some embodiments may include the display device 10 described above, and may further include a module or device having additional functions in addition to the display device 10.

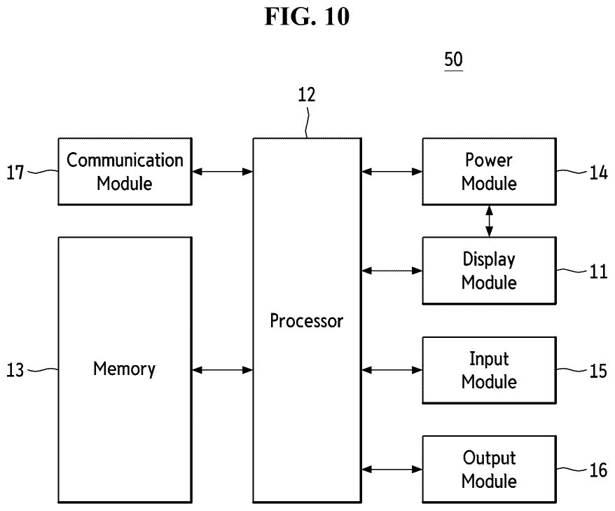

FIG. 10 is a block diagram of an electronic display device according to some embodiments. Referring to FIG. 10, an electronic device 50 according to some embodiments may include a display module 11, a processor 12, a memory 13, and a power module 14. The electronic device 50 may further include an input module 15, a non-image output module 16, and/or a communication module 17.

The electronic device 50 may output various information in the form of an image through the display module 11. When the processor 12 executes an application stored in the memory 13, image information provided by the application may be provided to the user through the display module 11. The power module 14 may include a power supply module, such as a power adapter or a battery device, and a power conversion module that converts power supplied by the power supply module to generate power required for an operation of the electronic device 50. The input module 15 may provide input information to the processor 12 and/or the display module 11. The non-image output module 16 may serve to receive information other than the image received from the processor 12, such as sound, haptics, and light emission, and provide the information to the user. The communication module 17 is a module responsible for transmitting and receiving information between the electronic device 50 and an external device, and may include a receiving unit and a transmitting unit.

At least one of the components of the electronic device 50 described above may be included in the display device according to the above-described embodiments. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device 50 other than the display device.

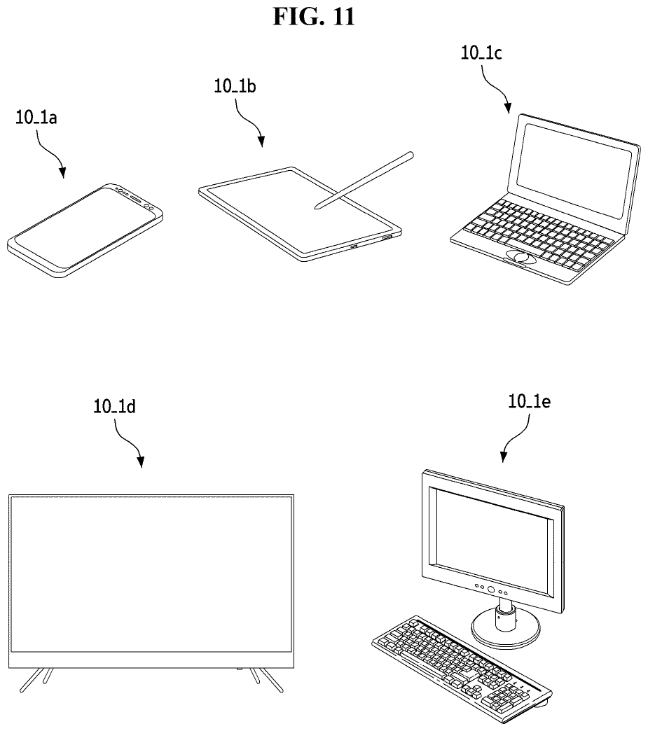

FIGS. 11, 12, and 13 are schematic diagrams of electronic devices according to various embodiments. FIGS. 11 to 13 illustrate examples of various electronic devices to which the display device 10 according to the embodiments is applied.

FIG. 11 illustrates examples of the electronic devices, including a smartphone 10_1a, a tablet PC 10_1b, a laptop 10_1c, a TV 10_1d, and a desk monitor 10_1e.

The smartphone 10_1a may include an input module such as a touch sensor and a communication module in addition to the display module 11. The smartphone 10_1a may process information received through the communication module or other input modules and display the information through the display module of the display device.

The tablet PC 10_1b, the laptop 10_1c, the TV 10_1d, and the desk monitor 10_1e also include a display module and an input module similarly to the smartphone 10_1a, and in some cases, may further include a communication module.

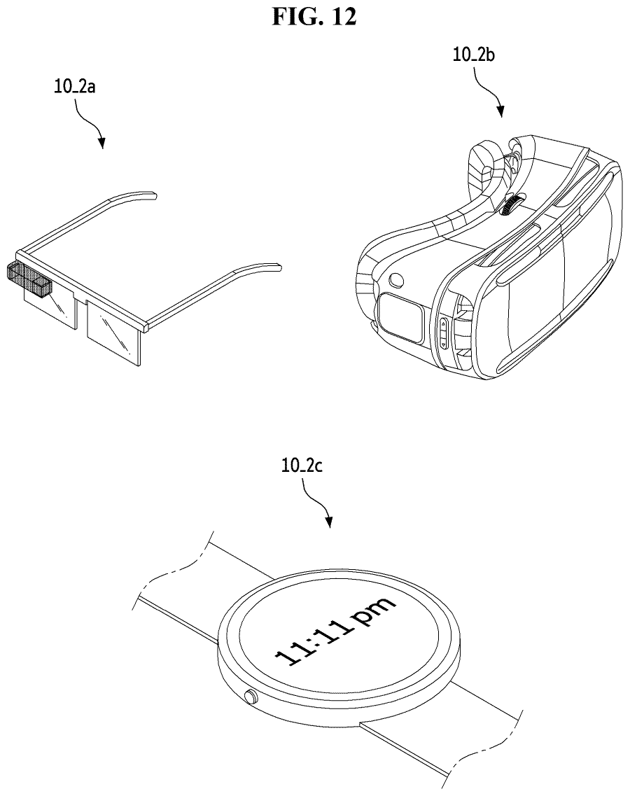

FIG. 12 illustrates an example in which an electronic device including a display module is applied to a wearable electronic device. The wearable electronic device may be a smart glasses 10_2a, a head mounted display 10_2b, a smart watch 10_2c, etc.

The smart glasses 10_2a and the head mounted display 10_2b may include a display module that emits a display image and a reflector that reflects the emitted display image and provides the reflected display image to the user's eyes, and may provide the user with a virtual reality or augmented reality screen through the display module and the reflector.

The smart watch 10_2c includes a biometric sensor as an input device and may provide the biometric information recognized by the biometric sensor to the user through the display module.

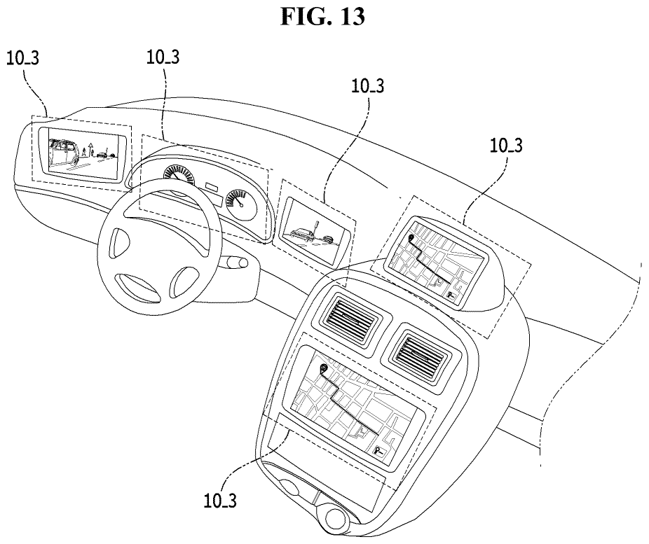

FIG. 13 illustrates an example in which an electronic device including a display module is applied to a vehicle. For example, an electronic device 10_3 may be applied to a dashboard, center fascia, etc. of an automobile, or may be applied to a Center Information Display (CID) located on the dashboard of the automobile or a room mirror display replacing a side mirror.

In concluding the detailed description, those skilled in the art will appreciate that many variations and modifications can be made to the disclosed embodiments without departing from the spirit and scope of embodiments according to the present disclosure. Therefore, the disclosed embodiments of the invention are used in a generic and descriptive sense only and not for purposes of limitation.

What is claimed is:

1. A display device comprising:
a main display panel including a first side extending along a first direction and a second side adjacent to the first side and extending along a second direction intersecting an extension direction of the first side;
a first sub-display panel on the first side of the main display panel and extending along the first direction;
a second sub-display panel on the second side of the main display panel and extending along the second direction;
a first sub-circuit board connected to the first sub-display panel so as to overlap a first side of the first sub-display panel; and
a second sub-circuit board connected to the second sub-display panel so as to overlap a first side of the second sub-display panel,
wherein the first side of the first sub-display panel extends in the first direction, and
the first side of the second sub-display panel extends in the second direction.

2. The display device of claim 1, further comprising:
a first signal line in a display area of the first sub-circuit board and extending along the first direction; and
a second signal line in a display area of the second sub-circuit board and extending along the first direction.

3. The display device of claim 2, wherein a length of the first signal line is greater than a length of the second signal line.

4. The display device of claim 3, wherein a width of the first signal line is greater than a width of the second signal line.

5. The display device of claim 2, further comprising a first sub-driving circuit on the first sub-circuit board,
wherein the first signal line is connected to one side and an other side of the first sub-circuit board.

6. The display device of claim 1, wherein a length of the first side of the first sub-display panel is equal to a sum of a length of the first side of the main display panel and a length of the second side of the second sub-display panel, and
the second side of the second sub-display panel is adjacent to the first side of the second sub-display panel and extends along the first direction.

7. The display device of claim 1, wherein a second side of the first sub-display panel faces the first side of the first sub-display panel, and
the second side of the first sub-display panel contacts the first side of the main display panel.

8. The display device of claim 7, wherein a third side of the main display panel faces the second side of the main display panel,
a third side of the first sub-display panel is on a same line as the third side of the main display panel,
an extension line of the second side of the main display panel is between the third side of the first sub-display panel and a fourth side of the first sub-display panel so as to overlap the first sub-display panel, and
the fourth side of the first sub-display panel faces the third side of the first sub-display panel.

9. The display device of claim 1, wherein a second side of the second sub-display panel faces the first side of the second sub-display panel, and
the second side of the second sub-display panel contacts the second side of the main display panel.

10. The display device of claim 9, wherein a fourth side of the main display panel faces the first side of the main display panel,
a third side of the second sub-display panel is on a same line as the first side of the main display panel,
an extension line of the fourth side of the main display panel is between the third side of the second sub-display panel and a fourth side of the second sub-display panel so as to overlap the second sub-display panel, and
the fourth side of the second sub-display panel faces the third side of the second sub-display panel.

11. The display device of claim 1, wherein a substrate of the main display panel includes silicon, and
a substrate of at least one of the first sub-display panel or the second sub-display panel includes glass.

12. The display device of claim 11, further comprising:
a MOS transistor on the substrate of the main display panel; and
an oxide semiconductor-based transistor on the substrate of at least one of the first sub-display panel or the second sub-display panel.

13. The display device of claim 1, wherein an area of a pixel of the main display panel is smaller than an area of a first pixel of the first sub-display panel.

14. The display device of claim 13, wherein an area of a light emitting area of the pixel is smaller than an area of a light emitting area of the first pixel.

15. The display device of claim 13, wherein the area of the first pixel is equal to an area of a second pixel of the second sub-display panel.

16. The display device of claim 15, wherein an area of a light emitting area of the first pixel is equal to an area of a light emitting area of the second pixel.

17. The display device of claim 1, further comprising:
a pixel on an upper surface of the main display panel; and
a main driving circuit on a lower surface of the main display panel.

18. An electronic device comprising:
a display device providing a display screen,
wherein the display device includes:
a main display panel including a first side extending along a first direction and a second side adjacent to the first side and extending along a second direction intersecting an extension direction of the first side;
a first sub-display panel on the first side of the main display panel and extending along the first direction;
a second sub-display panel on the second side of the main display panel and extending along the second direction;
a first sub-circuit board connected to the first sub-display panel so as to overlap a first side of the first sub-display panel; and
a second sub-circuit board connected to the second sub-display panel so as to overlap a first side of the second sub-display panel,
the first side of the first sub-display panel extends in the first direction, and
the first side of the second sub-display panel extends in the second direction.

19. The electronic device of claim 18, further comprising:
a first signal line in a display area of the first sub-circuit board and extending along the first direction; and
a second signal line in a display area of the second sub-circuit board and extending along the first direction,
wherein a length of the first signal line is greater than a length of the second signal line, and
a width of the first signal line is greater than a width of the second signal line.

20. The electronic device of claim 18, wherein the electronic device includes a smartphone, a tablet, a laptop, a TV, a desk monitor, a smart glasses, a smart watch, a head mounted display, or a vehicle.
